(19) United States
(12) Patent Application Publication
(10) Pub. No.: US 2002/0197403 A1
(43) Pub. Date: Dec. 26, 2002

(54) Methods for chemical vapor deposition of titanium-silicon-nitrogen films

(75) Inventors: Barry C. Arkles, Dresher, PA (US); Alain E. Kaloyeros, Slingerlands, NY (US)

Correspondence Address: AKIN, GUMP, STRAUSS, HAUER & FELD, L.L.P., ONE COMMERCE SQUARE, SUITE 2200, 2005 MARKET STREET, PHILADELPHIA, PA, 19103, US

(73) Assignee: Gelest, Inc., Morrisville, PA

(21) Appl. No.: 10/209,153

(22) Filed: Jul. 30, 2002

Related U.S. Application Data
(63) Continuation of application No. 09/835,271, filed on Apr. 13, 2001, now abandoned.
(60) Provisional application No. 60/196,798, filed on Apr. 13, 2000.

(51) Int. Cl. C23C 16/00

(52) U.S. Cl. 427/255.392; 427/255.393; 427/255.394; 427/569

(57) ABSTRACT

A method for chemical vapor deposition of a TiSiₓN_{y} film onto a substrate wherein x is greater than zero and no greater than about 5, and y is greater than zero and no greater than about 7, including introducing into a deposition chamber: (i) a substrate; (ii) a source precursor comprising titanium in a vapor state having the formula (I):

Ti(I_{4—m—n})(Brₘ)Cl(ₙ) (I)

wherein m is an integer from zero to 4, n is an integer from 0 to 2, and m+n is no greater than 4; (iii) a compound comprising silicon in a vapor state; (iv) a reactant gas comprising nitrogen; and maintaining a temperature of the substrate in the chamber at about 70° C. to about 550° C. for a period of time sufficient to deposit the TiSiₓN_{y} film on the substrate.

### CROSS-REFERENCE TO RELATED APPLICATIONS

This application claims the benefit of U.S. Provisional Application No. 60/196,798, filed Apr. 13, 2000.

### BACKGROUND OF THE INVENTION

As computer chip device dimensions continue their evolution towards feature sizes below 180 nm, new liner materials and associated process technologies are needed to ensure viable diffusion barrier and adhesion promoter performance between the conductor and the surrounding regions of silicon-based and dielectric-based materials. These liners must possess mechanical and structural integrity, good conformality within aggressive device features, high conductivity to minimize plug overall effective resistance, and thermal, mechanical, and electrical compatibility with neighboring conductor and dielectric materials systems. Most importantly, liner materials are expected to meet these stringent requirements at increasingly reduced thicknesses, in order to maximize the real estate available for the primary metal conductor within the continuously decreasing device dimensions. In particular, liner thickness is predicted to decrease from 20 nm for the 0.15 μm device generation, to less than 6 nm for its 0.05 μm counterpart as noted in the International Technology Roadmap for Semiconductors, 1999 Edition, Santa Clara, Calif., p. 165.

These stringent requirements for liner materials are further complicated by the fact that copper based interconnects have almost universally replaced their aluminum counterparts in high-performance integrated circuitry applications. This transition was driven by copper's lower resistivity and improved electromigration resistance, which allow faster signal propagation speed and higher performance characteristics. However, the successful incorporation of copper as the signal-carrying interconnect in emerging generations of sub-tenth-micron computer chip devices requires effective chemical, structural, mechanical, and electrical compatibility with the surrounding low dielectric constant insulators. Most of the resulting target specifications could be achieved through the identification of appropriate liners that prevent copper diffusion into the dielectric, and promote viable copper-dielectric interlayer adhesion. These liner materials are also required to be thermodynamically stable with respect to the copper and dielectric layers, and preferably exhibit an amorphous structure to eliminate the high diffusion pathways typically provided by grain boundaries. More importantly, they must sustain their desirable properties at extremely reduced thicknesses to ensure that most of the effective volume of the trench and via structures is occupied by the actual copper conductor.

In this respect, ternary refractory metal liners such as the titanium-silicon-nitrogen (TiSiₓN_{y}), tantalum-silicon-nitrogen (TaSiₓN_{y}), and tungsten-boron-nitrogen (WBₓN_{y}) systems, could act as viable diffusion barriers in copper metallization, due to their favorable chemical, structural, and thermal properties. In particular, the TiSiₓN_{y} phase represents a highly desirable option owing to the fact that Ti-based liners have already gained wide acceptance in semiconductor fabrication flows. In addition, the availability of TiSiₓN_{y} in amorphous form provides an added incentive, in view of the absence of grain boundaries that tend to act as fast diffusion paths for copper migration. In this respect, the amorphous TiSiₓN_{y} phase has been shown to be stable against recrystallization at temperatures as high as 1000° C., with the latter being strongly dependent on film stoichiometry. See X. Sun et al., Journal Applied Physics, volume 81(2), 656 (1997).

As a result, various research groups have investigated the formation of TiSiₓN_{y} films by a variety of physical vapor deposition (PVD) and metal-organic chemical vapor deposition (MOCVD) techniques, and documented their resulting performance as copper diffusion barriers. In the PVD case, most of the diffusion barrier studies employed liners of a thickness larger than 100 nm, See J. Reid et al., Thin Solid Films, volume 236, 319 (1993); P. Pokela et al., Journal of the Electrochemical Society, volume 138, 2125 (1991); and J. Reid et al., Journal of Applied Physics, volume 79, 1109-15 (1996). Consequently, the resulting findings and conclusions are inapplicable to sub-quarter-micron device structures. In addition, PVD techniques are inherently incapable of conformal step coverage in aggressive via and trench device structures, in view of their line of sight approach to film deposition. Therefore, alternate processing techniques are required for growing TiSiₓN_{y} films for applications in sub-quarter-micron devices. In this respect, inorganic chemical vapor deposition (CVD) and metal organic chemical vapor deposition (MOCVD) appear to be the most promising techniques.

Very little work has been performed regarding inorganic CVD TiSiₓN_{y} films. One MOCVD route has been identified for TiSiₓN_{y} films using the reaction of tetrakis diethylamido titanium (TDEAT), silane (SiH₄), and NH₃ to deposit TiSiₓN_{y} films over the temperature range from 300 to 450° C. See J. Custer et al., in Advanced Metallization and Interconnect Systems for ULSI Applications in 1995 (Materials Research Society, Pittsburgh, Pa. 1996), p. 343. Barrier thermal stress (BTS) testing was subsequently performed on 10 nm-thick Ti₂₃Si₁₄N₄₅_{O}₃C₃H₁₂ samples that were grown by MOCVD at 400° C. The samples were shown to possess a mean-time-to-failure (MTTF) which was approximately 10-100 times that of PVD TiN. See P. Smith et al., in Advanced Metallization and Interconnect Systems for ULSI Applications in 1995 (Materials Research Society, Pittsburgh, Pa. 1996), p. 249. However, the films were highly contaminated with carbon, oxygen, and hydrogen, a feature which is highly undesirable for applications in computer chip device technologies which require electronic grade film purity.

Furthermore, as device sizes are further reduced below 100 nm, predictions published in the International Technology Roadmap for Semiconductors-1999 Edition indicate the need for “zero thickness” liners, i.e., liners with a thickness as small as perhaps a few monolayers or less. These trends require the development and optimization of manufacturing-worthy processes for the reliable and reproducible deposition of conformal ultrathin liners with atomic level controllability. In response to these needs, work in the prior art has demonstrated that techniques such as atomic layer chemical vapor deposition (ALCVD) and atomic layer deposition (ALD) are viable methods for the deposition of ultrathin diffusion barrier liners, including binary and ternary titanium-based liners, and for incorporation in sub-tenth-micron semiconductor device fabrication flows. ALD techniques are almost universally based on the principle of self-limiting adsorption of individual monolayers of source precursor species on the substrate surface, followed by reaction with appropriately selected reactants to grow a single molecular layer of the desired material. Thicker films are produced through repeated growth cycles until the desired target thickness is met. See U.S. Pat. Nos. 5,972,430, 5,711,811, 4,389,973, and 4,058,430.

In the case of TiN_{X} liners, inorganic ALCVD methodology has focused on the thermal reaction of halide sources of the type tetraiodotitanium (TiI₄) and titanium tetrachloride (TiCl₄) with ammonia (NH₃), with zinc (Zn) being used in some experiments as an additional reactant in the case of TiCl₄ See P. Martensson et al., Journal of Vacuum Science and Technology, B17, 2122 (1999); M. Ritala et al., Journal Electrochemical Society, 142, 2731 (1995); M. Ritala et al., Applied Surface Science, 120, 199 (1997); M. Ritala et al., Journal of the Electrochemical Society, 145, 2914 (1998); M. Ritala et al., Chemical Vapor Deposition, 5, 7 (1999). See also M Leskelä et al., Journal De Physique IV, C5-937 (1995); J-S Min et al., Japanese Journal of Applied Physics, 9A, 4999 (1998). However, thus far there is generally a lack of an available process for the inorganic CVD of ternary liners and TiSiₓN_{y} in particular.

Alternatively, metalorganic atomic layer deposition (MOALD) has employed the sequential supply of tetrakis dimethylamido titanium (TDMAT), silane (SiH₄), and NH3, with an argon (Ar) pulse being inserted in between each reactant gas pulse, to deposit TiSiₓN_{y} films at 180° C. See J. Min et al., Applied Physics Letters, volume 75(11), 1521 (1999). No information was available in this work with regard to film purity, resistivity, or barrier properties. However, the use of silane is highly undesirable due to significant storage and handling challenges and serious safety concerns that are attributed to the pyrophoric nature of the silane source.

Thus far none of the prior approaches discussed above has led to the successful identification of a CVD process which is suitable for manufacturing ultrathin TiSiₓN_{y} liners for incorporation in sub-100 nm device technologies. Therefore, a need in the art exists for a method for providing TiSiₓN_{y} films, including those which are suitable for the manufacture of sub-100 nm computer devices. A need in the art also exists for TiSiₓN_{y} films of an electronic grade, i.e., of an especially ultra-high quality, in terms of stoichiometry and resistivity, which exhibit a non-columnar nanocrystalline or amorphous texture to perform appropriately as a diffusion barrier layer, and which are conformal to the complex topographies of sub-100 nm device structures.

There is further a need in the art for a method which can readily prepare TiSiₓN_{y} films with x, (the Si to Ti atomic ratio) being greater than zero and no greater than about 5, and y (the N to Ti atomic ratio) being greater than zero and no greater than about 7, since these represent TiSiₓN_{y} films with the stoichiometry necessary to achieve a structurally, chemically, and thermally stable phase, while maintaining a reasonably low film resistivity value. There is also need for a method which is amenable to process temperatures of about 550° C. or less to prevent thermally-induced damage to the device and surrounding dielectric regions during processing. There is further a need for a method which is capable of atomic level control in ultrathin film nucleation and growth, to allow the formation of appropriately dimensioned liners with tight compositional and textural control.

There is also a need in the art for chemically-engineered, highly maleable, and closely compatible titanium and silicon source precursors for use in atomically-tailored, interfacially-engineered, CVD and ALCVD processes for the depositon of highly conformal ultrathin TiSiₓN_{y} films, as thin as a few monolayers. Further, it would be desirable if these CVD and ALCVD processes were able to demonstrate the necessary ability to chemically and structurally “nanoengineer” the substrate surface through tightly controlled interactions with the chemically-engineered source precursors or appropriate source precursor intermediates to allow sequential atomic layer by atomic layer growth of films such as TiSiₓN_{y}.

### BRIEF SUMMARY OF THE INVENTION

The present invention includes a method for chemical vapor deposition of a TiSiₓN_{y} film onto a substrate wherein x is greater than zero and no greater than about 5, and y is greater than zero and no greater than about 7. The method comprises introducing into a deposition chamber the following components: (a) a substrate; (b) a source precursor comprising titanium in a vapor state having formula (I):

Ti(I_{4—m—n})(Brₘ)Cl(ₙ) (I)

where m is an integer from 0 to 4, n is an integer from 0 to 2, and m+n is no greater than 4; (c) a compound comprising silicon in a vapor state; and (d) a reactant gas comprising nitrogen. The temperature of the substrate in the chamber is maintained from about 70° C. to about 550° C. for a period of time sufficient to deposit the TiSiₓN_{y} film on the substrate.

In a further embodiment of the invention, a method for chemical vapor deposition of a TiSiₓN_{y} film onto a substrate wherein x is greater than zero and no greater than about 5, and y is greater than zero and no greater than about 7, comprises introducing into a deposition chamber (a) a substrate; (b) a source precursor comprising titanium in a vapor state having formula (I):

Ti(I_{4—m—n})(Brₘ)Cl(ₙ) (I)

wherein m is an integer from zero to 3, n is an integer from 0 to 2, and m+n is no greater than 3; (c) a compound comprising silicon in a vapor state having formula (II);

Si(I_{4—m—n—p})(Br_{m—p})Cl(_{n—p})(Rₚ) (II)

wherein m is an integer from 0 to 3, n is an integer from 0 to 3, p is an integer from 0 to 3, m+n+p is no greater than 3, and R is selected from a group consisting of hydrogen and lower alkyl; and (d) a reactant gas comprising nitrogen. The temperature of the substrate in the chamber is maintained from about 70° C. to about 550° C. for a period of time sufficient to deposit the TiSiₓN_{y} film on the substrate.

The present invention further includes a method for forming a film containing titanium, nitrogen and silicon by atomic layer chemical vapor deposition. The method includes: (a) introducing into a deposition chamber a substrate having a surface, and heating the substrate to a temperature sufficient to allow adsorption of a source precursor comprising titanium onto the substrate surface; (b) introducing the source precursor comprising titanium into the deposition chamber by pulsing the source precursor comprising titanium to expose the substrate surface to the source precursor comprising titanium for a period of time sufficient to form an adsorbed layer of the source precursor comprising titanium or an intermediate thereof on the substrate surface; (c) introducing a first purging gas into the deposition chamber by pulsing for a period of time sufficient to remove unadsorbed source precursor comprising titanium or the intermediate thereof; (d) introducing a gas comprising nitrogen capable of reacting with the adsorbed source precursor comprising titanium or the intermediate thereof by pulsing the gas comprising nitrogen for a period of time sufficient to react with the adsorbed source precursor comprising titanium or the intermediate thereof in a first reaction, thereby forming a first reaction product on the substrate surface; (e) introducing an inert gas into the deposition chamber by pulsing the inert gas for a period of time sufficient to remove the gas comprising nitrogen; (f) introducing a compound comprising silicon into the deposition chamber by pulsing the compound comprising silicon for a period of time sufficient to allow adsorption of the compound comprising silicon on the first reaction product on the substrate surface; (g) introducing a second purging gas into the deposition chamber by pulsing the purging gas for a period of time sufficient to remove unadsorbed compound comprising silicon; (h) introducing a gas comprising nitrogen capable of reacting with the adsorbed compound comprising silicon by pulsing the gas comprising nitrogen for a period of time sufficient to react the gas comprising nitrogen with the compound comprising silicon that has adsorbed on the first reaction product in a second reaction, thereby forming a second reaction product on the first reaction product on the surface of the substrate; (i) introducing a third purging gas into the deposition chamber for a period of time sufficient to remove the gas comprising nitrogen.

In a further embodiment of the invention, a method for forming a film comprising titanium, nitrogen and silicon by atomic layer chemical vapor deposition comprises (a) introducing into a deposition chamber a substrate having a surface, and heating the substrate to a temperature sufficient to allow adsorption of a source precursor comprising titanium onto the substrate; (b) introducing the source precursor comprising titanium into the deposition chamber by pulsing the source precursor comprising titanium to expose the substrate surface to the source precursor comprising titanium for a period of time sufficient to form an adsorbed layer of the source precursor comprising titanium or an intermediate thereof on the substrate surface, wherein the source precursor comprising titanium has formula (I)

Ti(I_{4—m—n})(Brₘ)Cl(ₙ) (I)

wherein m is an integer from 0 to 3, n is an integer from 0 to 2, and m+n is no greater than 3; (c) introducing a first purging gas into the deposition chamber by pulsing for a period of time sufficient to remove the unadsorbed source precursor comprising titanium or the intermediate thereof; (d) introducing a gas comprising nitrogen capable of reacting with the source precursor comprising titanium or the intermediate thereof adsorbed on the substrate surface by pulsing the gas comprising nitrogen for a period of time sufficient to react with the adsorbed source precursor comprising titanium or the intermediate thereof in a first reaction, thereby forming a first reaction product on the substrate surface; (e) introducing an inert gas into the deposition chamber by pulsing the inert gas for a period of time sufficient to remove the gas comprising nitrogen; (f) introducing a compound comprising silicon into the deposition chamber by pulsing the compound comprising silicon for a period of time sufficient to allow adsorption of the compound comprising silicon on the first reaction product, wherein said compound comprising silicon has formula (II)

Si(I_{4—m—n—p})(Br_{m—p})Cl(_{n—p})(Rₚ) (II)

wherein m is an integer from 0 to 3, n is an integer from 0 to 3, p is an integer from 0 to 3, m+n+p is no greater than 3, and R is selected from the group consisting of hydrogen and lower alkyl; (g) introducing a second purging gas into the deposition chamber by pulsing the purging gas for a period of time sufficient to remove the unadsorbed compound comprising silicon; (h) introducing a gas comprising nitrogen capable of reacting with the compound comprising silicon that has adsorbed on the first reaction product by pulsing the gas comprising nitrogen for a period of time sufficient to react the gas comprising nitrogen with the compound comprising silicon that has adsorbed on the first reaction product in a second reaction, thereby forming a second reaction product on the first reaction product on the surface of the substrate; and (i) introducing a third purging gas into the deposition chamber for a period of time sufficient to remove the gas comprising nitrogen.

### BRIEF DESCRIPTION OF THE SEVERAL VIEWS OF THE DRAWINGS

The foregoing summary, as well as the following detailed description of preferred embodiments of the invention, will be better understood when read in conjunction with the appended drawings. For the purpose of illustrating the invention, there is shown in the drawings embodiments which are presently preferred. It should be understood, however, that the invention is not limited to the precise arrangements and instrumentalities shown.

In the drawings:

FIG. 1 is a representation of Rutherford backscattering spectroscopy (RBS) spectra of as-deposited CVD-grown TiSiₓN_{y} films formed in accordance with Example 1;

FIG. 2 is a representation of an x-ray photoelectron spectroscopy (XPS) depth profile spectra of as-deposited CVD-grown TiSiₓN_{y} films formed in accordance with Example 1;

FIG. 3 is a representation of the x-ray diffraction (XRD) pattern of as-deposited CVD-grown, 25 nm-thick, TiSiₓN_{y} films formed in accordance with Example 1;

FIG. 4 is a representation of a cross-section TEM-magnified view of a representative silicon substrate upon which oxide trench patterns, of nominal diameter 130 nm and 100:1 aspect ratio, are formed and upon which a conformal TiSiₓN_{y} coating formed in Example 1 has been deposited; and

FIG. 5 is a representation of RBS spectra of Cu/CVD-grown TiSiₓN_{y}/Si stacks which are formed in accordance with Example 1, and subsequently annealed at: (a) 600° C., and (b) 700° C. The RBS spectra were collected after removal of the top copper layer.

### DETAILED DESCRIPTION OF THE INVENTION

The present invention relates to TiSiₓN_{y} films formed from titanium and silicon source precursors and a reactant gas containing nitrogen, and associated methods for the CVD and ALCVD of such films. As used herein, the term CVD refers to a process where all reactants are introduced into a CVD reactor in a vapor state, and the energy necessary for bond cleavage is supplied either by thermal energy, or by electronic energy in a plasma, or both. The film stoichiometry in the CVD process is preferably tightly controlled by adjusting the flows of a titanium-containing source precursor, a silicon-based compound and a nitrogen-containing gas into the reactor. In the ALCVD process, according to the invention, thermal energy is used for bond cleavage, and the stoichiometry of the film is controlled by varying the number and duration of individual pulses of the titanium-containing source precursor, the silicon-based compound, and the nitrogen-containing reactant gas into the ALCVD reactor. In this way, a film having multiple layers can be formed.

While there may be some impurities present in the TiSiₓN_{y} films of the invention which are residual components from the deposition reactants, such as halogen, oxygen, and carbon, it is preferred that the films have very low impurity concentrations, preferably less than 1 at % each for oxygen, carbon, and halogen.

The deposition reactors suitable for the CVD and ALCVD processes according to the invention should preferably have several basic components: a precursor and reactant gas delivery system, a vacuum deposition chamber and pumping system to maintain an appropriate pressure, a power supply to create discharge as necessary, a temperature control system, and gas or vapor handling capabilities to control the flow of reactants and products from the reactor.

As used herein, substrates can include both coated and uncoated substrates. Uncoated subtrates include those materials such as are noted below. Coated substrates may include substrates with layers, liners or barriers such as are typically encountered in ultra-large scale integrated (ULSI) circuitry. The films of the present invention are useful on semiconductor substrates including silicon, germanium and gallium arsenide, and III-V semiconductors including indium phosphide. In microelectronic applications, a preferred substrate is intended to become an integrated circuit, and has a complex topography formed of holes, trenches, vias, etc., to provide the necessary connections between materials of various electrical conductivities that form a semiconductor device. The substrate is preferably formed of, for example, silicon, silicon dioxide on silicon, as in a silicon wafer that has been oxidized, silicon nitride on silicon, as where a layer of silicon nitride has been deposited on a silicon wafer, or doped versions thereof.

The substrates of the invention are more preferably intended for ULSI circuitry, and are patterned with holes, trenches and other features with diameters of less than 1.0 micron, often less than 0.25 microns, and even 0.1 micron or less. Substrates having such small features are known herein as sub-micron substrates. Sub-micron features which may be coated according to the invention also typically have features with ultra-high aspect ratios, from about 6:1 to about 20:1, where the term “aspect ratio” is defined as the ratio of a feature's depth to its diameter, as viewed in cross-section. As used herein, sub-micron substrates have feature diameters of less than about one micron and the aspect ratio of the features is larger than about 3:1 Features having an aspect ratio of about 6:1 to about 20:1 are found on typical substrates for ULSI and gigascale integration (GSI).

Examples of substrates which may be coated include semiconductor substrates as mentioned above, or metal, glass, plastic, or other polymers, for applications including, for example, hard protective coatings for aircraft components and engines, automotive parts and engines and cutting tools; cosmetic coatings for jewelry; and barrier layers and adhesion promoters for flat panel displays and solar cell devices. Preferred metal substrates include aluminum, beryllium, cadmium, cerium, chromium, cobalt, copper, gallium, gold, lead, manganese, molybdenum, nickel, palladium, platinum, rhenium, rhodium, silver, steel, including stainless steel, iron, strontium, tin, titanium, tungsten, zinc, zirconium, alloys thereof and compounds thereof, such as silicides, carbides and the like.

There is no limitation on the type of substrate which can be used in the present method. However, the substrate is preferably stable to temperatures of from about 70° C. to about 600° C., and preferably from about 300° C. to about 450° C., depending on the type of film to be deposited and the intended use of the coated substrate.

In forming a TiSiₓN_{y} film using a CVD growth mode, a substrate, a titanium-containing source precursor in a vapor state, a silicon-based compound in a vapor state, and a nitrogen-containing reactant gas are introduced into the deposition chamber of the CVD reactor. The deposition chamber is then heated so as to maintain the temperature of the substrate within the chamber from about 70° C. to about 550° C., and preferably from about 200° C. to about 450° C. for a period of time sufficient to deposit a TiSiₓN_{y} film onto the substrate.

The titanium-containing source precursor preferably has formula (I) below:

Ti(I_{4—m—n})(Brₘ)(Clₙ) (I)

wherein m is an integer from 0 to 4, n is an integer from 0 to 2, and m+n is no greater than 4. More preferably, the titanium-containing source precursor according to formula (I) above is titanium tetraiodide, Ti₄, or titanium tetrabromide, TiBr₄.

The silicon-based compound preferably complies with formula (II) below:

Si(I_{4—m—n—p})(Br_{m—p})Cl(_{n—p})(Rₚ) (II)

wherein m is an integer from 0 to 4, n is an integer from 0 to 4, p is an integer from 0 to 4, m+n+p is no greater than 4, and R is preferably hydrogen or a lower alkyl such as methyl, ethyl, isobutyl and propyl. More preferably, the silicon-based compound is silicon tetraiodide, SiI₄, or methyltriiodosilane, CH₃SiI₃.

The nitrogen-containing gas may be nitrogen, ammonia, hydrazine, nitrous oxide or any other suitable nitrogen-containing gas capable of reacting with the titanium-containing source precursor or the silicon-based compound. Preferably, the nitrogen-containing gas is ammonia.

At least one additional gas such as hydrogen, helium, neon, argon, krypton, xenon, and carbon dioxide can also be introduced into the deposition chamber as a carrier gas.

In the present invention, deposition times can range between less than one minute to over five hours depending on the type of film to be deposited, the processing conditions, the desired film thickness, the type of reactant gas and the precursors used. The pressure of the deposition chamber is maintained from about 10 Pa to about 1500 Pa. The flowrate of the nitrogen-containing gas to the deposition chamber is maintained from about 0.1 liter/min to about 1 liter/min. The preferred flowrate of the nitrogen-containing gas is from about 0.1 liter/min to about 0.5 liter/min. The most preferred flowrate of the nitrogen-containing gas is from about 0.15 liter/min to about 0.25 liter/min. The flowrate of the titanium-containing source precursor to the deposition chamber is maintained from about 0.001 liter/min to about 0.5 liter/min. The preferred flowrate of the titanium-containing source precursor is from about 0.001 liter/min to about 0.05 liter/min. The most preferred flowrate of the titanium-containing source precursor is from about 0.002 liter/min to about 0.025 liter/min. The flowrate of the silicon-based compound is maintained from about 0.0 liter/min to about 0.5 liter/min, preferably from about 0.001 liter/min to about 0.05 liter/min. The most preferred flowrate of the silicon-based compound is from about 0.002 liter/min to about 0.025 liter/min.

Optionally, a plasma may be introduced to the deposition chamber to supply energy for the film-forming reactions. When a plasma is used, it is preferred that the plasma have a power density of from about 0.01 to about 10 W/cm² and a frequency of from about 0 Hz to about 10⁸ kHz. The plasma would be introduced into the deposition chamber for a period sufficient to deposit the TiSiₓN_{y} film.

An electrical bias may also optionally be applied to the substrate. The source of the electrical bias can include at least one of a direct current bias, a low radio frequency bias of less than 500 kHz, a high radio frequency bias of from 500 kHz to 10⁶ kHz, and a microwave frequency bias of from 10⁶ kHz to about 10⁸ kHz bias. When an electrical bias is used, it is preferred that the electrical bias has a power density greater than 0 W/cm² and less than 10³ W/cm².

The TiSiₓN_{y} films of the present invention can also be formed using an ALCVD film forming process. For the ALCVD method, a substrate is introduced into the deposition chamber, and is heated to a temperature sufficient to allow adsorption of a titanium-containing source precursor onto the substrate. Preferably, the substrate temperature is maintained from about 25° C. to about 500° C. A titanium-containing source precursor is then introduced into the deposition chamber by pulsing the titanium-containing source precursor for a period of time sufficient to form an adsorbed layer of the precursor, or an intermediate thereof, on the surface of the substrate. The titanium-containing source precursor preferably has formula (I) described above. Preferably, the period of time for pulsing is about 0.5 seconds to about 100 seconds. Preferably, the flow rate of the pulsed titanium-containing source precursor is about 0.0001 liter/min to about 0.1 liter/min.

A purging gas is then introduced into the deposition chamber for a period of time sufficient to remove any of the unadsorbed titanium-containing source precursor or intermediates thereof. The purging gas includes those gases which do not react with the deposited film, and can include one or more of hydrogen, helium, neon, argon, krypton, xenon, and carbon dioxide. Preferably, the period of time for pulsing the purging gas is from about 0.75 seconds to about 500 seconds. Preferably, the flowrate of the pulsed purging gas is from about 0.0001 liter/min to about 0.5 liter/min.

A nitrogen-containing gas that is capable of reacting with the titanium-containing source precursor or an intermediate thereof adsorbed on the surface of the substrate, is next introduced into the deposition chamber. The nitrogen-containing gas, which includes the nitrogen-containing gases as described above in the CVD process, is introduced into the deposition chamber by pulsing the gas for a period of time sufficient to react the gas with the adsorbed titanium-containing source precursor or an intermediate thereof, in a first reaction, thereby forming a first reaction product on the surface of the substrate. Preferably, the period of time for pulsing the nitrogen-containing gas is from about 0.5 seconds to about 100 seconds. Preferably, the flow rate of the pulsed nitrogen-containing gas is about 0.0001 liter/min to about 0.1 liter/min.

An inert gas is then introduced into the deposition by pulsing the inert gas for a period of time sufficient to remove the nitrogen-containing gas. The inert gas is inert with respect to the source precursors as they are transported, does not participate in the reactions of the deposition process, does not react with the deposited film, and typically can consist of one or more of helium, nitrogen, argon, xenon, or krypton. Preferably the period of time for removal of the nitrogen-containing gas is from about 0.5 seconds to about 100 seconds. Preferably, the flow rate of the pulsed inert gas is from about 0.0001 liter/min to about 0.5 liter/min.

A silicon-based compound is next introduced into the deposition chamber by pulsing the compound for a period of time sufficient to allow adsorption of the silicon-based compound on the first reaction product on the substrate surface. The silicon-based compound preferably has formula (II) described above. Preferably, the period of time for pulsing the silicon-based compound is from about 0.5 seconds to about 100 seconds. Preferably, the flow rate of the pulsed silicon-based compound is from 0.0001 liter/min to about 0.1 liter/min.

A purging gas, as described above, is then introduced into the deposition chamber by pulsing the purging gas for a period of time sufficient to remove any unadsorbed compound comprising silicon. Preferably, the period of time for pulsing the purging gas is from about 0.75 seconds to about 500 seconds. Preferably, the flow rate of the purging gas is from about 0.0001 liter/min to about 0.5 liter/min.

A nitrogen-containing gas, as described above, that is capable of reacting with the compound comprising silicon that has been adsorbed on the first reaction product is next introduced into the deposition chamber. The nitrogen-containing gas is pulsed into the deposition chamber for a period of time sufficient to react the nitrogen-containing gas, in a second reaction, with the silicon-based compound that has been adsorbed on the first reaction product. A second reaction product is thereby formed on the first reaction product on the surface of the substrate. Preferably, the period of time for pulsing the nitrogen-containing gas is from about 0.5 seconds to about 100 seconds. Preferably, the flow rate of the pulse of nitrogen-containing gas is about 0.0001 liter/min to about 0.1 liter/min.

Finally, a purging gas, as described above, is introduced into the deposition chamber for a period of time sufficient to remove the nitrogen-containing gas. Preferably, the period of time for pulsing the purging gas is from about 0.75 seconds to about 500 seconds. Preferably, the flow rate for the pulsed purging gas is from about 0.0001 liter/min to about 0.5 liter/min.

The above-described steps in the ALCVD film-forming process can be sequentially repeated to form a multilayer TiSiₓN_{y} film of a desired thickness as measured transversely across the film. Preferably, the thickness of such a film produced by the ALCVD process is less than 10 μm, however the thickness can be larger as the needs of the application require.

Illustrated below are exemplary chemical reaction formulas of the present invention, wherein titanium tetraiodide is used as the preferred titanium-containing source precursor and silicon tetraiodide is the preferred silicon-based compound.

Plasma-promoted or thermal CVD:

TiI₄+SiI₄+NH₃+H₂NH_{q}XIᵣTiSiₓN_{y}+NH_{q′}I_{r′}+HI (major byproducts)

Plasma-promoted or thermal CVD:

TiI₄+SiI₄+NH₃NH_{q}XIᵣTiSiₓN_{y}+NH_{q′}I_{r′}(major byproduct)

Plasma-promoted or thermal CVD:

TiI₄+SiI₄+N₂+H₂NH_{q}XIᵣTiSiₓN_{y}+HI (major byproduct)

wherein NH_{q}XIᵣ(X=Si, Ti) refers to reaction intermediates that are adducts of the various reactants, where q ranges from 0 to 3 and r ranges from 1 to 4, and wherein x and y are as defined above. These intermediates play a critical role in ensuring that the reaction proceeds along pathways that result in the deposition of a pure and stoichiometric TiSiₓN_{y} phase that is free of any halide incorporation. NH_{q′}I_{r′} are ammonium halide type species, where q′ ranges from 0 to 3 and r′ ranges from 1 to 4. Hydrogen also served as an additional reactant in ensuring the complete passivation and elimination of any free iodide reaction byproducts from the reaction zone, by reacting with iodide reaction byproducts.

The invention will now be further illustrated in accordance with the following non-limiting example.

### EXAMPLE 1

TiSiₓN_{y} films were prepared in a standard alpha-type, 200 mm-wafer, warm-wall, plasma-capable CVD reactor equipped with a high vacuum load lock for wafer transport and handling without exposing the deposition chamber to air. This approach allowed tight control over process stability and reproducibility. The chamber was also equipped with a parallel-plate-type, radio-frequency (rf) plasma capability for in-situ wafer plasma cleaning. A roots blower stack was used for process pumping. The TiI₄ and SiI₄ source precursors, which are solid at room temperature, were delivered to the reaction chamber using individual MKS Model 1153A Vapor Source Delivery Systems. Sufficient vapor pressure for delivery to the chamber was achieved by heating each source to approximately 160° C., with the delivery systems and transport lines being kept approximately 180° C. to prevent precursor recondensation. This delivery approach did not require carrier gas, and allowed repeatable control over reactant flows to the process chamber.

Ammonia (NH₃) and hydrogen (H₂) were used as co-reactants. Undesirable gas phase reactions were eliminated through the use of a “no-mix” showerhead architecture, where the ammonia line was isolated from all other reactants until introduction in the reaction zone. For all depositions, three types of substrates were employed. Si (100) wafers were employed for thermal diffusion barrier testing, while 500 nm-thick thermally grown SiO₂ on Si were applied for composition, resistivity and texture measurements, and patterned oxide structures were used for assessment of film conformality. Table 1 summarizes the pertinent deposition parameters and corresponding ranges evaluated.

The composition, microstructure, surface morphology, conformality, and electrical properties of the CVD Ti—Si—N films were analyzed by x-ray photoelectron spectroscopy (XPS), Rutherford backscattering spectrometry (RBS), x-ray diffraction (XRD), transmission electron microscopy (TEM), and four-point resistivity probe. In this respect, selected film properties are summarized in Table 2.

XPS analyses were performed on a Perkin-Elmer PHI 5500 multi-technique system with spherical capacitor analyzer. The gold f_{7/2} line was used as a reference and the analyzer calibrated accordingly. The primary x-ray beam was generated with a monochromatic Al Kα x-ray source at operating power of 300W and 15 keV applied to the anode. The use of Al Kα primary x-rays allowed the elimination of undesirable interference between the Co LMM and O1s peaks. Depth profiles were acquired after a 30s or 1 min long sputter clean cycle. The oxygen 1s peak window (544 to 526 eV) was scanned first after each sputtering cycle in order to avoid any potential oxygen loss in the vacuum system.

X-ray diffraction analysis were done on a Scintag XDS 2000 x-ray diffractometer, equipped with a Cu Kα x-ray source and a horizontal wide angle four axis goniometer with stepping motors, which allowed independent or coupled θ-2θ axes motion. XRD spectra for CVD Co were collected in both normal (Bragg-Bretano) and 5 low angle incidence geometry, and compared to the reference patterns in the Joint Committee for Powder Diffraction Standards (JCPDS) Powder Diffraction File (PDF).

Rutherford backscattering spectroscopy (RBS) was employed to determine film thickness and composition. For this purpose, RBS data was compiled using a 2MeV He⁺ beam on a 4.5MeV Dynamitron model P.E.E. 3.0 linear accelerator.

HRTEM was carried out on a JOEL 2010F field emission electron microscope operating at 200 kV. Imaging was performed with the sample titled so that the Si<110>zone axis was perpendicular to the incident beam. Cross section TEM specimens were prepared by standard sample preparation procedures, including mechanical sample polishing, dimpling and argon ion milling. TEM analysis was performed on the thinnest region (<50 nm) adjacent to the center hole in the sample.

Four point resistivity probe measurements were performed using a KLA Tencor Four Point Probe to determine sheet resistance. The film resistivity was then calculated using the thickness values.

TABLE 1

| Parameter | Processing range investigated | |
|---|---|---|
| Wafer Temperature | 350 to 430° | C. |
| Process Pressure | 10 to 150 | pascals |
| NH₃ Flow | 0.1 to 0.25 | liter/min |
| H₂ Flow | 0.100 | liter/min |
| TiI₄ Gaseous Flow | 0.0025 to 0.006 | liter/min |
| SiI₄ Gaseous Flow | 0.0 to 0.0125 | liter/min |

TABLE 2

| Property | Value |
|---|---|
| Optimized Composition | Ti₃₃Si₁₅N₅₁ (TiSi_{0.455}N_{1.55}) |
| (RBS, XPS) | |
| Compositional Range | 0 ≦ x ≦ 5 |
| (RBS, XPS) | 0 ≦ x ≦ 7 |
| Iodine Incorporation | Approx. 1.4 at % |
| (RBS) | |
| Oxygen Incorporation | Typical XPS |
| (XPS) | Background Levels |
| Texture | Nanocrystalline TiN phase |
| (XRD, TEM) | within An amorphous |
| | SiN matrix |
| Resistivity | Approx. 800 μΩcm |
| (25 nm-thick film) | |
| Conformality | 50% |
| (130 nm-wide, 10:1 aspect ratio trenches) | |

Additionally, a preliminary evaluation was carried out on the performance of the CVD TiSiₓN_{y} as a diffusion barrier in copper metallization. For this purpose, 100 nm-thick Cu films were ex-situ sputter-deposited on 25 nm-thick CVD Ti₃₃Si₁₅N₅₁ (TiSi_{0.455}N_{1.55}) films grown on Si. The resulting stacks were annealed in one atmosphere of argon at 450° C., 515° C., 600° C., and 700° C. for 30 minutes, along with sputter-deposited Cu/CVD TiN/Si stacks of identical thickness. The latter provided a comparative assessment of barrier performance. After annealing, the copper was stripped off in a diluted nitric acid solution, and the resulting samples were then analyzed by RBS to detect the presence of Cu, either in the liner material, or in the underlying Si substrate.

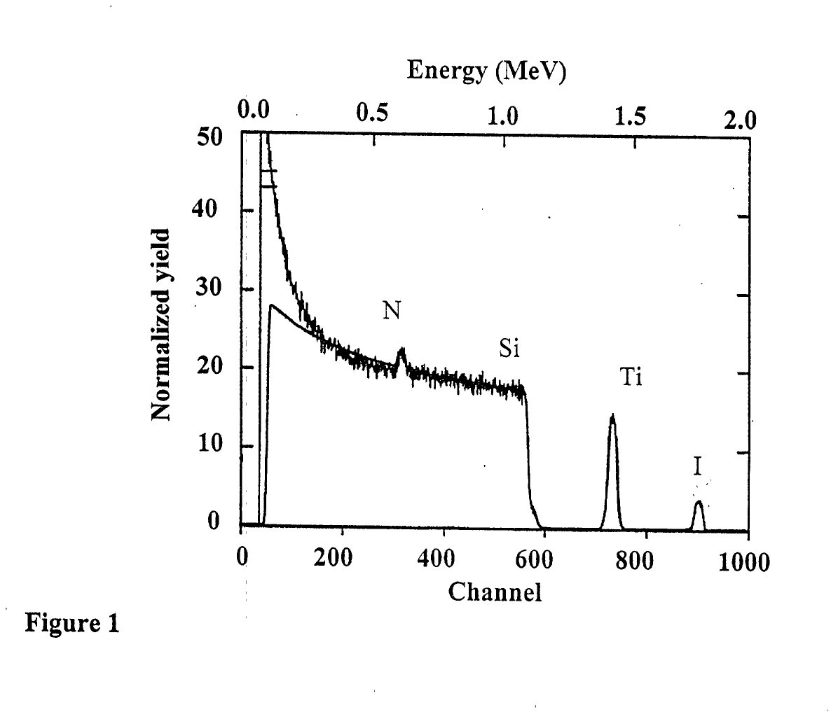

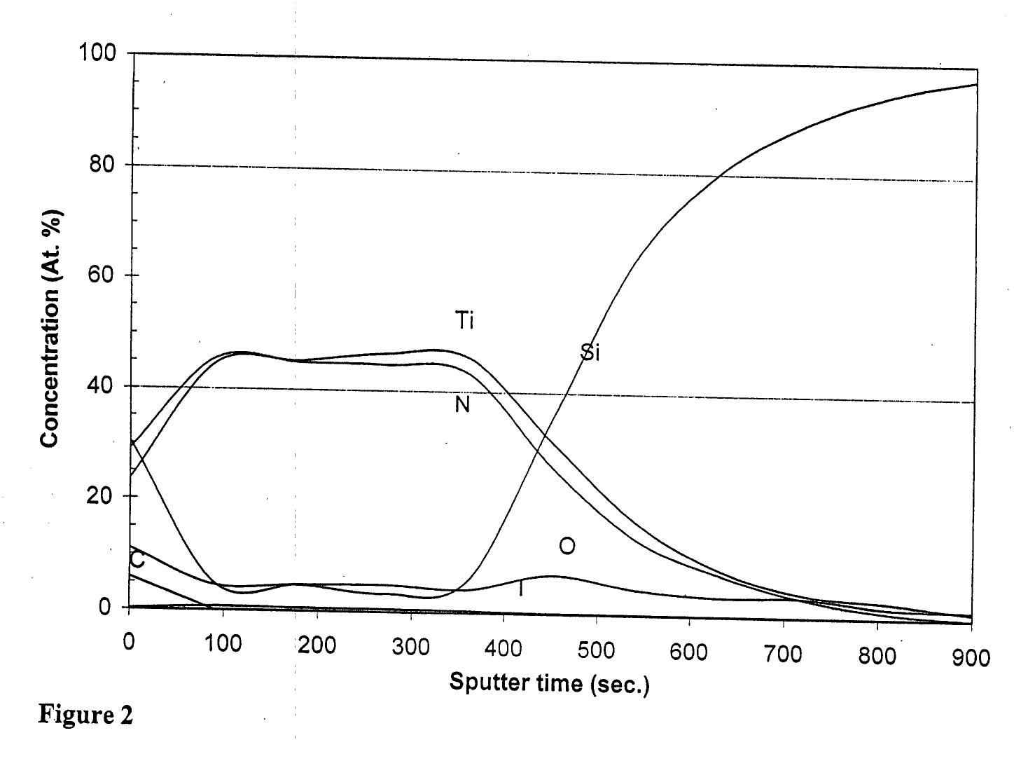

FIG. 1 presents the typical RBS spectrum of an 82 nm-thick CVD TiSiₓN_{y} film deposited on Si at a wafer temperature of 430° C. RBS analysis indicated that the films were free of any heavy elemental contaminants, with the exception of approximately 1.4 at % iodine. XPS depth profiling yielded an optimized composition of Ti₃₃Si₁₅N₅₁. In this respect, higher NH₃ and SiI₄ flows at constant TiI₄ flow yielded, respectively, increased nitrogen and silicon incorporation in the resulting TiSiₓN_{y} phase. For illustration purposes, FIG. 2 displays the XPS depth profile for the same type sample shown in FIG. 1. The XPS depth profile yielded an optimized film composition of Ti₃₃Si₁₅N₅₁ (TiSi_{0.455}N_{1.55}), and indicated the presence of oxygen levels of approximately 3 at %, which was within the typical background levels of the XPS system.

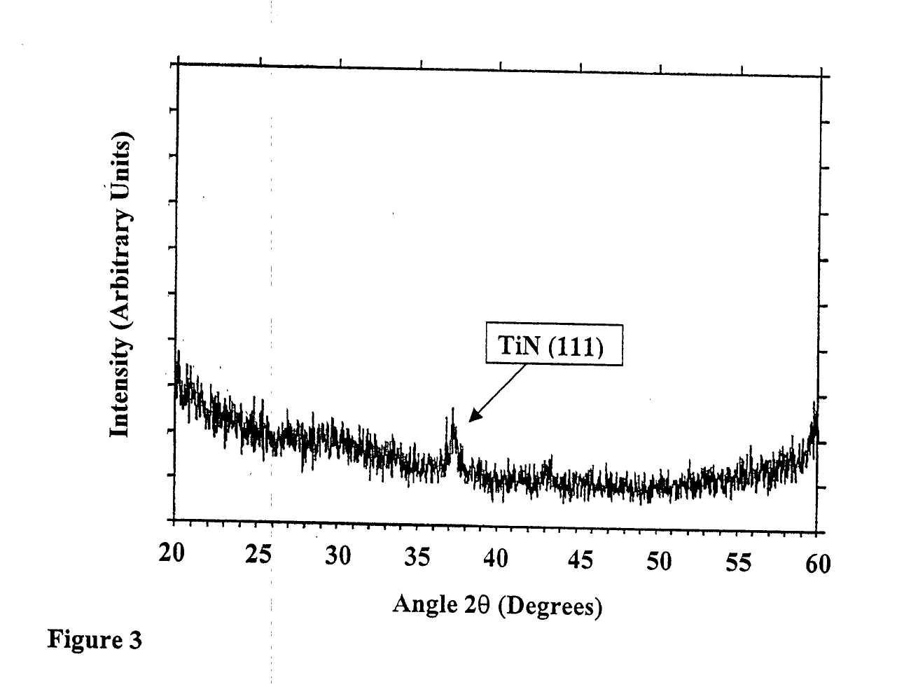

FIG. 3 presents the typical XRD spectrum of a 25 nm-thick CVD TiSiₓN_{y} film grown on SiO₂. The only XRD peak detected was ascribed to the (111) reflection from TiN. It is believed that this finding indicates that film microstructure consisted of a nanocrystallline TiN phase within an amorphous SiN matrix, in agreement with prior results in the literature on sputter-deposited TiSiₓN_{y} films. It was suggested that this TiSiₓN_{y} microstructure is desirable from a diffusion barrier performance perspective, especially in view of the absence of grain boundaries. The latter tend to act as fast diffusion paths for copper migration.

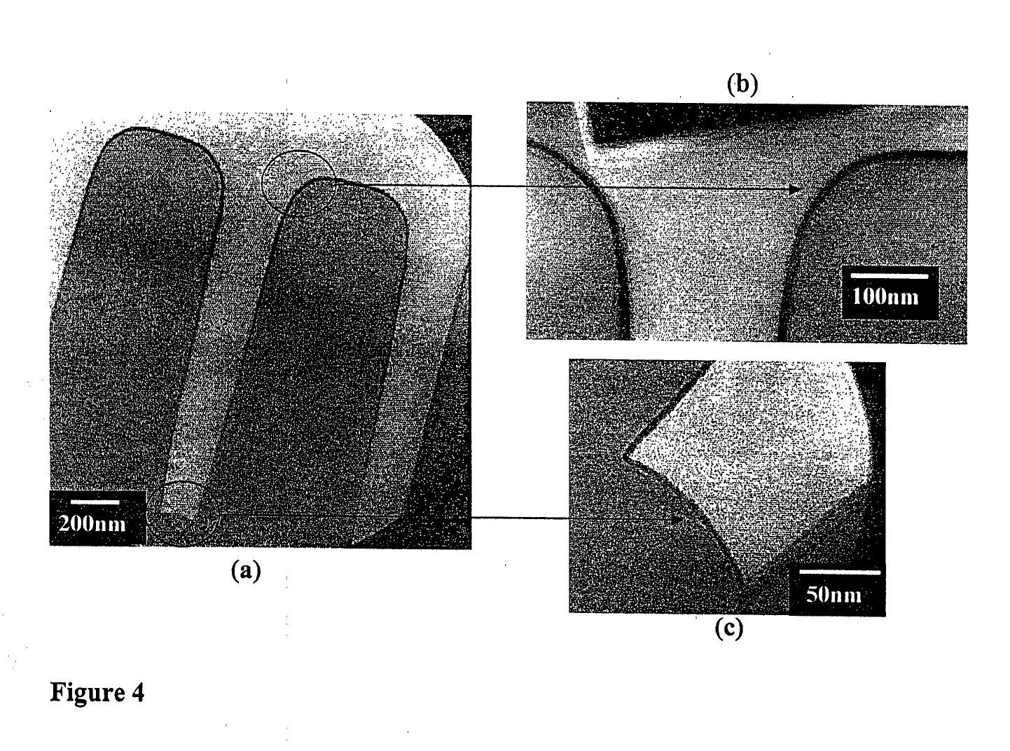

Transmission electron microscopy (TEM) was applied to determine film conformality in aggressive device structures. In this respect, FIG. 4(a) exhibits the bright field TEM micrograph of a 10 nm-thick CVD-grown Ti—Si—N in a nominal 130 nm-wide, 10:1 aspect ratio, trench structure. In addition, FIGS. 4(b) and 4(c) display higher magnification TEM images of film profiles at, respectively, the top and bottom of the trench structure. TEM analysis yielded a film conformality of approximately 50%, and indicated the absence of thinning or loafing effects at the top and bottom corners of the trench structure. TEM imaging also confirmed the XRD results with respect to the existence of a nanocrystalline structural phase.

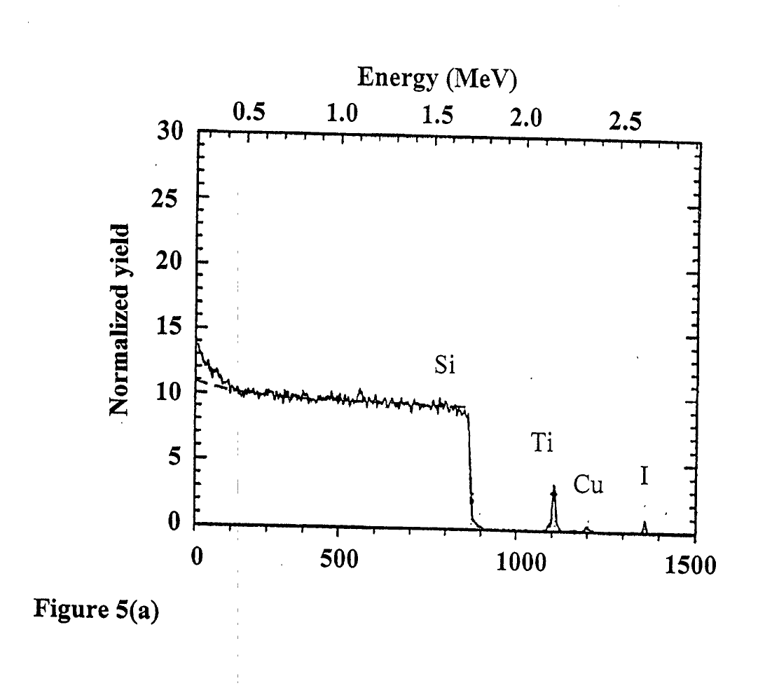

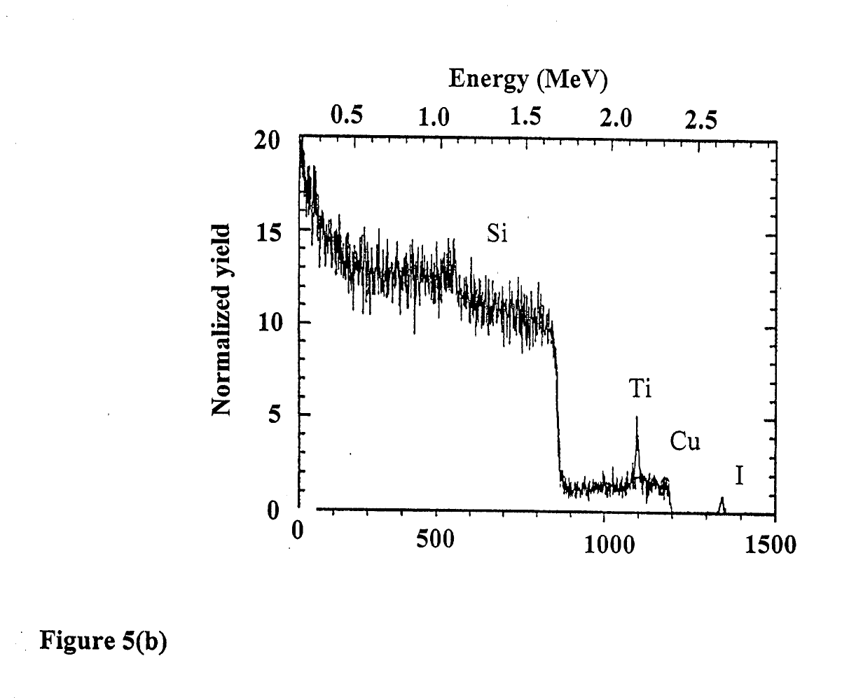

In terms of diffusion barrier performance, RBS results indicated the absence of any diffused copper in the CVD TiSiₓN_{y} liner or underlying Si substrates after annealing at 600° C., as shown in FIG. 5(a). In contrast, RBS detected the onset of copper diffusion for the same film after annealing at 700° C., as shown in FIG. 5(b).

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

As can be seen from the results above, the invention provides highly conformal TiSiₓN_{y} films for use in applications that require films as thin as a few monolayers.

We claim:

1. A method for chemical vapor deposition of a TiSiₓN_{y} film onto a substrate wherein x is greater than zero and no greater than about 5, and y is greater than zero and no greater than about 7, comprising:
(a) introducing into a deposition chamber:
(i) a substrate;
(ii) a source precursor comprising titanium in a vapor state having formula (I):
Ti(I_{4—m—n})(Brₘ)Cl(ₙ) (I)
wherein m is an integer from zero to 4, n is an integer from 0 to 2, and m+n is no greater than 4;
(iii) a compound comprising silicon in a vapor state;
(iv) a reactant gas comprising nitrogen; and
(b) maintaining a temperature of the substrate in the chamber at about 70° C. to about 550° C. for a period of time sufficient to deposit the TiSiₓN_{y} film on the substrate.

2. The method according to claim 1, wherein the substrate temperature is about 200 C. to about 450 C.

3. The method according to claim 1, wherein the substrate comprises silicon dioxide on silicon.

4. The method according to claim 1, wherein the source precursor comprising titanium is TiI₄.

5. The method according to claim 1, wherein-the reactant gas comprising nitrogen is selected from the group consisting of nitrogen, ammonia, hydrazine and nitrous oxide.

6. The method according to claim 5, wherein the reactant gas is ammonia.

7. The method according to claim 1, wherein the compound comprising silicon has formula (II):
Si(I_{4—m—n—p})(Br_{m—p})Cl(_{n—p})(Rₚ) (II)
wherein m is an integer from 0 to 4, n is an integer from 0 to 4, p is an integer from 0 to 4, m+n+p is no greater than 4, and R is selected from a group consisting of hydrogen and lower alkyl.

8. The method according to claim 7, wherein the compound comprising silicon in a vapor state is SiI₄.

9. The method according to claim 1, further comprising introducing into the deposition chamber at least one second gas selected from the group consisting of hydrogen, helium, neon, argon, krypton, xenon, and carbon dioxide.

10. The method according to claim 1, further comprising introducing into the chamber a plasma having a plasma power density of about 0.01 W/cm² to about 10 W/cm².

11. The method according to claim 10, wherein the plasma has a frequency of about 0 Hz to about 10⁸ kHz.

12. The method according to claim 1, further comprising applying an electrical bias to the substrate, wherein the electrical bias is at least one of a direct current bias, a low radio frequency bias of less than 500 kHz, a high radio frequency bias of from 500 kHz to 10⁶ kHz, or a microwave frequency bias of from 10⁶ kHz to about 10⁸ kHz bias.

13. The method according to claim 12, wherein the electrical bias has a power density greater than 0 W/cm² and less than or equal to about 10³ W/cm².

14. A method for forming a film comprising titanium, nitrogen and silicon by atomic layer chemical vapor deposition comprising:
(a) introducing into a deposition chamber a substrate having a surface, and heating the substrate to a temperature sufficient to allow adsorption of a source precursor comprising titanium onto the substrate surface;
(b) introducing the source precursor comprising titanium into the deposition chamber by pulsing the source precursor comprising titanium to expose the substrate surface to the source precursor comprising titanium for a period of time sufficient to form an adsorbed layer of the source precursor comprising titanium or an intermediate thereof on the substrate surface;
(c) introducing a first purging gas into the deposition chamber by pulsing for a period of time sufficient to remove unadsorbed source precursor comprising titanium or the intermediate thereof;
(d) introducing a gas comprising nitrogen capable of reacting with the adsorbed source precursor comprising titanium or the intermediate thereof by pulsing the gas comprising nitrogen for a period of time sufficient to react with the adsorbed source precursor comprising titanium or the intermediate thereof in a first reaction, thereby forming a first reaction product on the substrate surface;
(e) introducing an inert gas into the deposition chamber by pulsing the inert gas for a period of time sufficient to remove the gas comprising nitrogen;
(f) introducing a compound comprising silicon into the deposition chamber by pulsing the compound comprising silicon for a period of time sufficient to allow adsorption of the compound comprising silicon on the first reaction product on the substrate surface;
(g) introducing a second purging gas into the deposition chamber by pulsing the purging gas for a period of time sufficient to remove unadsorbed compound comprising silicon;
(h) introducing a gas comprising nitrogen capable of reacting with the adsorbed compound comprising silicon by pulsing the gas comprising nitrogen for a period of time sufficient to react the gas comprising nitrogen with the compound comprising silicon that has adsorbed on the first reaction product in a second reaction, thereby forming a second reaction product on the first reaction product on the surface of the substrate; and
(i) introducing, a third purging gas into the deposition chamber for a period of time sufficient to remove the gas comprising nitrogen.

15. The method according to claim 14, wherein the substrate temperature is about 25° C. to about 550° C.

16. The method according to claim 14, wherein the source precursor comprising titanium has formula (I):
Ti(I_{4—m—n})(Brₘ)Cl(ₙ) (I)
wherein m is an integer from 0 to 4, n is an integer from 0 to 2, and m+n is no greater than 4.

17. The method according to claim 14, wherein the compound comprising silicon has formula (II):
Si(I_{4—m—n—p})(Br_{m—p})Cl(_{n—p})(Rₚ) (II)
wherein m is an integer from 0 to 4, n is an integer from 0 to 4, p is an integer from 0 to 4, m+n+p is no greater than 4, and R is selected from the group consisting of hydrogen and lower alkyl.

18. The method according to claim 14, wherein steps (b) through (i) are repeated until a film comprising titanium, nitrogen and silicon having a thickness measured transversely across the film no greater than about 10 μm is formed.

19. The method according to claim 14, wherein the purging gas is selected from the group consisting of hydrogen, helium, neon, argon, krypton, xenon, and carbon dioxide.

20. The method according to claim 14, wherein the gas comprising nitrogen is selected from the group consisting of nitrogen, ammonia, hydrazine, and nitrous oxide.

21. The method according to claim 14, wherein the period of time for pulsing the source precursor comprising titanium is about 0.5 seconds to about 100 seconds.

22. The method according to claim 14, wherein the period of time for pulsing the compound comprising silicon is about 0.5 seconds to about 100 seconds.

23. The method according to claim 14, wherein the period of time for pulsing the gas comprising nitrogen is about 0.5 seconds to about 100 seconds in steps (d) and (h).

24. The method according to claim 14, wherein the period of time for pulsing the purging gas is about 0.75 seconds to about 500 seconds in steps (c), (g) and (i).

25. A coated substrate, comprising a substrate coated on at least one side with a TiSiₓN_{y} film, wherein x is greater than zero and no greater than about 5, and y is greater than zero and no greater than about 7, and where the TiSiₓN_{y} film is a reaction product of a source precursor comprising titanium, a compound comprising silicon and a gas comprising nitrogen.

26. A method for chemical vapor deposition of a TiSiₓN_{y} film onto a substrate wherein x is greater than zero and no greater than about 5, and y is greater than zero and no greater than about 7, comprising:
(a) introducing into a deposition chamber:
(i) a substrate;
(ii) a source precursor comprising titanium in a vapor state having formula (I):
Ti(I_{4—m—n})(Brₘ)Cl(ₙ) (I)
wherein m is an integer from zero to 3, n is an integer from 0 to 2, and m+n is no greater than 3;
(iii) a compound comprising silicon in a vapor state having formula (II);
Si(I_{4—m—n—p})(Br_{m—p})Cl(_{n—p})(Rₚ) (II)
wherein m is an integer from 0 to 3, n is an integer from 0 to 3, p is an integer from 0 to 3, m+n+p is no greater than 3, and R is selected from a group consisting of hydrogen and lower alkyl.
(iv) a reactant gas comprising nitrogen; and
(b) maintaining a temperature of the substrate in the chamber at about 70° C. to about 550° C. for a period of time sufficient to deposit the TiSiₓN_{y} film on the substrate.

27. A method for forming a film comprising titanium, nitrogen and silicon by atomic layer chemical vapor deposition comprising:
(a) introducing into a deposition chamber a substrate having a surface, and heating the substrate to a temperature sufficient to allow adsorption of a source precursor comprising titanium onto the substrate surface;
(b) introducing the source precursor comprising titanium into the deposition chamber by pulsing the source precursor comprising titanium to expose the substrate surface to the source precursor comprising titanium for a period of time sufficient to form an adsorbed layer of the source precursor comprising titanium or an intermediate thereof on the substrate surface, wherein the source precursor comprising titanium has formula (I)
Ti(I_{4—m—n})(Brₘ)Cl(ₙ) (I)
wherein m is an integer from 0 to 3, n is an integer from 0 to 2, and m+n is no greater than 3;
(c) introducing a first purging gas into the deposition chamber by pulsing for a period of time sufficient to remove the unadsorbed source precursor comprising titanium or the intermediate thereof;
(d) introducing a gas comprising nitrogen capable of reacting with the source precursor comprising titanium or the intermediate thereof adsorbed on the substrate surface by pulsing the gas comprising nitrogen for a period of time sufficient to react with the adsorbed source precursor comprising titanium or the intermediate thereof in a first reaction, thereby forming a first reaction product on the substrate surface;
(e) introducing an inert gas into the deposition chamber by pulsing the inert gas for a period of time sufficient to remove the gas comprising nitrogen;
(f) introducing a compound comprising silicon into the deposition chamber by pulsing the compound comprising silicon for a period of time sufficient to allow adsorption of the compound comprising silicon on the first reaction product on the substrate surface, wherein the compound comprising silicon has formula (II)
Si(I_{4—m—n—p})(Br_{m—p})Cl(_{n—p})(Rₚ) (II)
wherein m is an integer from 0 to 3, n is an integer from 0 to 3, p is an integer from 0 to 3, m+n+p is no greater than 3, and R is selected from the group consisting of hydrogen and lower alkyl.;
(g) introducing a second purging gas into the deposition chamber by pulsing the purging gas for a period of time sufficient to remove the unadsorbed compound comprising silicon;
(h) introducing a gas comprising nitrogen capable of reacting with the compound comprising silicon that has adsorbed on the first reaction product by pulsing the gas comprising nitrogen for a period of time sufficient to react the gas comprising nitrogen with the compound comprising silicon that has adsorbed on the first reaction product in a second reaction, thereby forming a second reaction product on the first reaction product on the surface of the substrate; and
(i) introducing a third purging gas into the deposition chamber for a period of time sufficient to remove the gas comprising nitrogen.
